(19) United States
(12) Patent Application Publication
(10) Pub. No.: US 2012/0224319 A1
(43) Pub. Date: Sep. 6, 2012

(54) NOTEBOOK COMPUTER ASSEMBLY AND SUPPORTING APPARATUS FOR NOTEBOOK COMPUTER

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/076,466

(22) Filed: Mar. 31, 2011

(30) Foreign Application Priority Data
Mar. 3, 2011 (CN) 201110051062.1

(51) Int. Cl. G06F 1/16; H05K 7/14

(52) U.S. Cl. 361/679.27; 248/121

(57) ABSTRACT

A notebook computer assembly includes a notebook computer and a supporting apparatus. The notebook computer includes a main body and a display pivotably attached to the main body. The supporting apparatus includes a receiving portion for receiving the display of the notebook computer, with the main body keeping an angle with the display ranging from about 0 degrees to about 180 degrees.

### BACKGROUND

1. Technical Field

The disclosure relates to a notebook computer assembly and a supporting apparatus for the notebook computer.

2. Description of Related Art

Although notebook computers may be considered convenient and small, when not in use, a notebook computer just takes up space when horizontally set on a desk.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a first exemplary embodiment of a notebook computer assembly.

FIG. 2 and FIG. 3 are assembled views of FIG. 1, but showing different states of use.

FIG. 4 is an assembled, isometric view of a second exemplary embodiment of a notebook computer assembly.

### DETAILED DESCRIPTION

The disclosure, including the accompanying drawings, is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

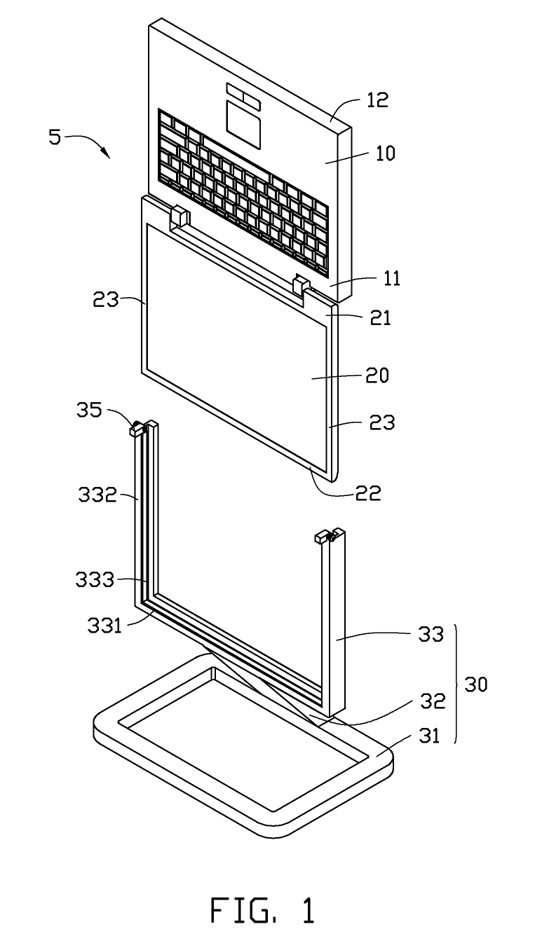

Referring to FIG. 1, a first exemplary embodiment of a notebook computer assembly includes a notebook computer 5 and a supporting apparatus 30. The notebook computer 5 includes a main body 10 and a display 20 pivotably connected to the main body 10 by hinges. The display 20 includes a first side 21, a second side 22 opposite to the first side 21, and two third sides 23 connected between corresponding ends of the first and second sides 21 and 22. The main body 10 includes a first side 11 pivotably connected to the first side 21 of the display 20, and a second side 12 opposite to the first side 11.

The supporting apparatus 30 includes a base 31, a support portion 32 extending upward slantingly from a side of the base 31, and a receiving portion 33 formed from a top of the supporting portion 32. The receiving portion 33 is substantially perpendicular to the base 31. The base 31 is a substantially rectangular frame. The receiving portion 33 is substantially U-shaped and includes a bottom section 331 and two parallel side sections 332 extending up from opposite ends of the bottom section 331. A substantially U-shaped receiving channel 333 is defined in the receiving portion 33, extending through inner surfaces of the bottom and side sections 331 and 333. A limiting member 35 is pivotably attached to a top of each of the side sections 333, opposite to the bottom section 331.

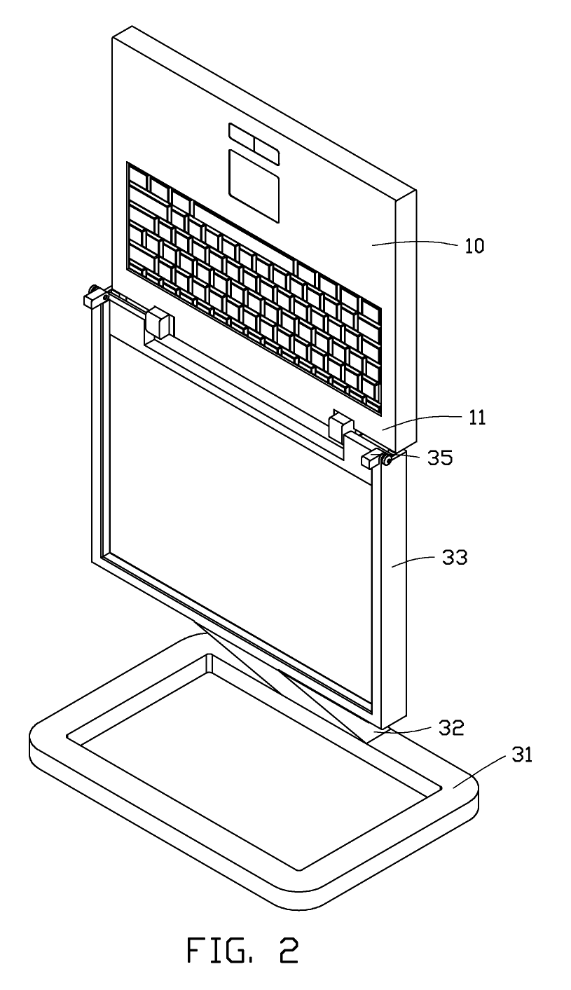

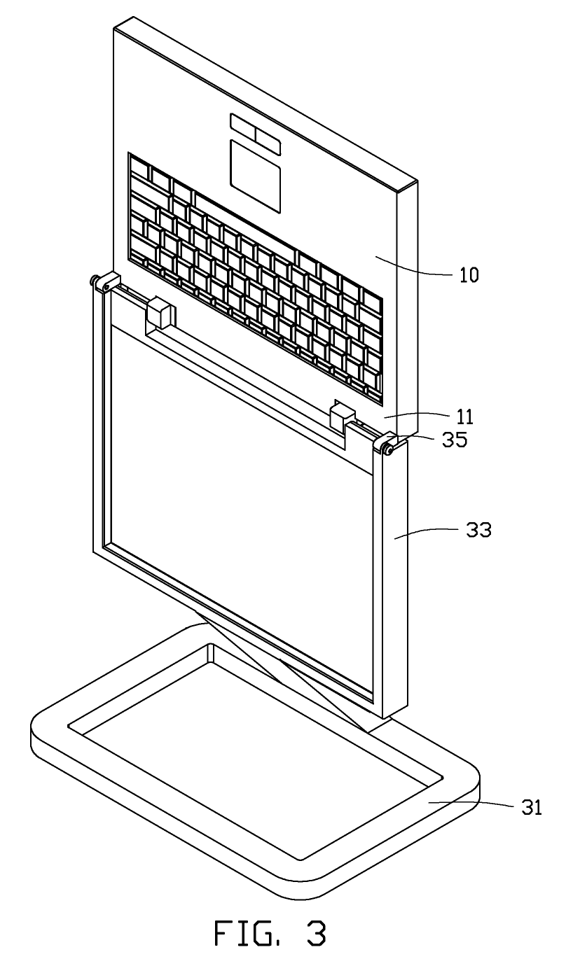

Referring to FIGS. 2 and 3, in use, the base 31 of the supporting apparatus 30 is set on a supporting surface, such as a desktop. The display 20 of the notebook computer 5 is pivoted to splay the second side 22 of the display 20 from the second side 12 of the main body 10, until an angle between the display 20 and the main body 10 is about 180 degrees. The second side 22 and third sides 23 of the display 20 are positioned in the receiving channel 333 of the receiving portion 33. The limiting members 50 are rotated to resist against the first side 11 of the main body 10, thereby preventing collapse of the main body 10.

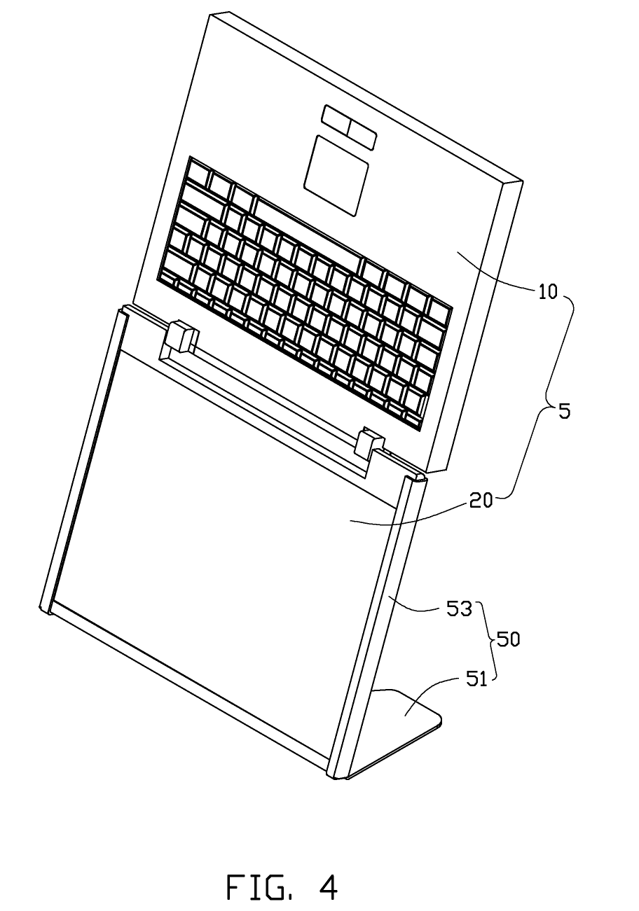

Referring to FIG. 4, a second exemplary embodiment of a notebook computer assembly includes a notebook computer 5 and a supporting apparatus 50. The notebook computer 5 includes a main body 10 and a display 20 pivotably connected to the main body 10 by hinges. The supporting apparatus 50 includes a base 51 and a receiving portion 53 slantingly extending up from a side of the bottom portion 51. The receiving portion 53 is used for receiving the display 20 of the notebook computer 5.

In the disclosures, when the notebook computer 5 is not in use, the notebook computer 5 can be collapsed to be stored in an upright position on the desktop, which can save space.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A notebook computer assembly comprising:
a notebook computer comprising a main body and a display pivotably connected to the main body; and
a supporting apparatus comprising a receiving portion for receiving the display of the notebook computer, with the main body keeping an angle with the display ranging from about 0 degrees to about 180 degrees.

2. The notebook computer assembly of claim 1, wherein the display of the notebook computer comprises a first side, and a second side opposite to the first side, the main body comprises a first side pivotably connected to the first side of the display, and a second side opposite to the first side of the main body.

3. The notebook computer assembly of claim 1, wherein the supporting apparatus comprises a base, and a supporting portion slantingly extending up from a side of the base, the receiving portion is formed from a top of the supporting portion.

4. The notebook computer assembly of claim 3, wherein the base is a substantially rectangular frame.

5. The notebook computer assembly of claim 3, wherein the receiving portion is substantially U-shaped and comprises a bottom section and two parallel side sections extending up from opposite ends of the bottom section.

6. The notebook computer assembly of claim 5, wherein a receiving channel is defined in the receiving portion, extending through inner surfaces of the bottom section and the side sections, three sides of the display of the notebook computer different from a side of the display connected to the main body are received in the receiving channel.

7. The notebook computer assembly of claim 5, wherein a limiting member is pivotably attached to each of the side sections opposite to the bottom section, the limiting members are rotatable to resist against the first side of the main body of the notebook computer to prevent collapse of the main body.

8. A supporting apparatus for a notebook computer, the supporting apparatus comprising:
a base;
a supporting portion slantingly extending up from a side of the bottom portion; and
a receiving portion formed from a top of the supporting portion, to receive a display of the notebook computer.

9. The supporting apparatus of claim 8, wherein the bottom portion is a substantially rectangular frame.

10. The supporting apparatus of claim 8, wherein the receiving portion is substantially U-shaped and comprises a bottom section and two parallel side sections extending up from opposite ends of the bottom section.

11. The supporting apparatus of claim 10, wherein a receiving channel is defined in the receiving portion, extending through inner surfaces of the bottom section and the side sections, to receive top and opposite sides of the display of the notebook computer.

12. The supporting apparatus of claim 10, wherein a limiting member is pivotably attached to each of the side sections, opposite to the bottom section, to be operable to pivot to resist against a main body of the notebook computer.
